(19) United States
(12) Patent Application Publication
(10) Pub. No.: US 2017/0283588 A1
(43) Pub. Date: Oct. 5, 2017

(54) LIGHT EMITTING DIODE BASED DAYLIGHT RUNNING LIGHT

(71) Applicant: DSM IP ASSETS B.V., Heerlen (NL)

(72) Inventors: Richard Jacques Theodoor FRISSEN, Echt (NL); Siva Esakimuthu SUBRAMONIAN, Echt (NL)

(21) Appl. No.: 15/508,179

(22) PCT Filed: Jul. 20, 2015
(86) PCT No.: PCT/EP2015/066565

§ 371 Date: Mar. 2, 2017

(30) Foreign Application Priority Data
Sep. 5, 2014 (EP) 14183770.8

(51) Int. Cl. C08K 7/14; H05K 1/03; F21S 8/10; C08K 5/00; B60Q 1/18; H01L 33/62; C08K 3/00

(52) U.S. Cl. CPC C08K 7/14; H01L 33/62; H05K 1/0366; C08K 3/0033; C08K 5/0008; B60Q 1/18; F21S 48/215; F21S 48/115; H05K 2201/0145; H05K 2201/0293; H05K 2201/10106; F21Y 2115/10

(57) ABSTRACT

Light emitting diode (LED) based daylight running light (DRL) comprising a carrier, comprising a polymer composition comprising polyethylene terephthalate and glass fibers, the surface of the carrier comprises conductor tracks for mounting one or more LED's.

A daytime running light (DRL), also called daytime running lamp is an automotive lightning and bicycle lightning device on front of a road going motor vehicle or bicycle, eventually automatically switching on when the vehicle is moving forward, emitting white, yellow or amber light to increase the visibility of the vehicle during daylight conditions.

The daylight running light was first mandated, and safety benefits perceived in Scandinavian countries, where it is persistently dark during the winter season.

The daylight running light function was originally implemented by operating the low-beam headlamps or even fog lamps at full or reduced intensity, by operating the high-beam headlamps at reduced intensity, or by steady burning he front turn signals.

European Union Directive 2008/89/EC requires all passenger cars and small delivery vans first type approved on or after 7 Feb. 2011 in the EU to come equipped with daytime running lights. The mandate was extended to trucks and buses in August 2012. Providing a DLR in a double function, such as operating the headlamps or front turn signals or fog lamps as DRLs, is not permitted anymore and the EU Directive requires functionally specific daytime running lamps compliant with ECE Regulation 87 and mounted to the vehicle in accord with ECE Regulation 48 DRLs compliant with R87 emit white light of between 400 and 1200 candela. Also in other countries in the world DRL is mandatory.

DLR power consumption varies widely depending on the implementation. By far the lowest energy consumption is obtained with DRL systems based on light emitting diodes (LED). Therefore such systems are supported by the European Union and are regarded as giving sufficient increase in safety while hardly increasing the fuel consumption. Often a beam of several LED's is used, sometimes build in the headlamp of the motor vehicle.

State of the art LED based DRL as brought onto the market is based on a carrier of polycarbonate, and a film of polyimid, comprising a structure of conductor tracks on the film. The film is mounted with metal clips on the carrier. The LED's are soldered on the conductor tracks of the film. Between the film and the carrier there is a gap order to ensure that the carrier is not heated by the LED's.

A problem of the known LED based DRL is that it is costly, because it is very difficult to produce. A further problem is that the whole assembly must be rejected after production, if only one of the components fail. Still a further problem is that the known LED based DRL shows a lot of failure during use.

In US 2013/0193452 a LED system is disclosed having a bent layered structure conformed to a three dimensional carrier, also called heat sink. The bent layered structure comprises a similar film of polyimid, comprising a structure of conductor tracks on the film. The LED's are soldered on the conductor tracks of the film. The three dimensional carrier is of a thermally conductive material, like aluminum or thermally conductive polymers. The system may be applied in all kind of lamps, however DLR is not mentioned.

A problem of the LED based DRL known from US 2013/0193452 is that it is still costly, because it is very difficult to produce. A further problem is that the whole assembly must be rejected after production, if only one of the components fail.

Object of the invention is to provide a LED based DRL that has a much simpler structure, so that it does not show above-mentioned problems.

Surprisingly this object has been obtained by providing an LED based DRL comprising a carrier, comprising a polymer composition comprising polyethylene terephthalate, glass fibers and Laser Directed Structure (LDS) additives, the conductor tracks being provided by a LDS process and subsequent metal plating, preferably copper-nickel-gold plating.

In this way a DRL has been obtained with a very simple structure, the carrier being one integrated single part. The DRL is easy to produce, the rejection after production is very low, due to high LED precision, and also the failure of the DRL is also very low. Furthermore the carrier shows low outgassing, which is for example very important when the DRL is integrated in the head lamp. Surprisingly the composition has a very good flow behavior, despite the presence of the glass fibers and the LDS additives in the composition. Finally the screw resistance of the composition is high. This enables the carrier to be mounted to the car by standard screw fixation, while offering still sufficient car/road vibration mode resistance.

The DRL according to the invention may comprise between 5 and 30 LED's. Preferably the DRL comprises between 15 and 25 LED,s. Preferably the LED's consume per LED less than 2 Watt at 12 Volt, more preferably less than 1 Watt, even more preferably less than 0.75 Watt. This ensures sufficient visibility, low energy consumption and a moderate heating up of the carrier.

The polyethylene terephthalate polymer is a polyester comprising terephthalic acid and ethylene glycol as monomeric units. The polyethylene terephthalate may also contain small amounts of further diacids, like isophtalic acid, or small amounts of further diols, like diethylene glycol as comonomers. Preferably the composition of the carrier contains at least a polyethylene terephthalate homopolymer. A polyethylene terephthalate homopolymer is herein understood to contain less than 5 mol % of monomer units other than those of terephthalic acid and ethylene glycol. The advantage of such a homopolymer is a higher melting point and better crystallisation behaviour. More preferably the polyethylene terephthalate homopolymer contains less than 4 mol %, even more preferably less than 3 mol % and most preferably less than 2 mol % of monomer units other than those of terephthalic acid and ethylene glycol. Preferably at least 50 weight (wt) % of polyethylene terephthalate in the composition is the homopolymer, more preferably at least 90 wt. %, most preferably at least 95 wt. %.

The polyethylene terephthalate may have a relative solution viscosity (RSV, determined on a solution of 1 gram polymer in 125 grams of a 7/10 (m/m) trichlorophenol/phenol mixture at 25° C.; method based on ISO 1628-5) of from 1.50 to 2.00, preferably 1.60-1.85, and most preferably 1.65-1.80. Generally a higher RSV will result in improved strength and toughness of a composition, whereas a lower RSV promotes melt flow and crystallisation speed. With the present RSV range an optimum in performance is reached, without the need for adding impact-modifiers or flow-promoters, which is favourable for even further extending the service fife of the RF housing. In order to arrive at these RSV values, the polyethylene terephthalate may have been post-condensed in the solid state, for example by exposing the composition in granular form to an elevated temperature of up to about 10° C. below its melting point, in an inert atmosphere during several hours. Another advantage of such a solid state post-condensation is that any volatiles present in the composition, and that may affect processing behaviour of the composition or properties of a part moulded thereof, are substantially removed.

The polymer composition preferably contains a nucleating agent to enhance the crystallisation of the polyethylene terephthalate. As a nucleating agent any known nucleating agents may be used. Preferably inorganic additives like micro-talcum, or a metal-carboxylate, especially an alkalimetal-carboxylate like sodium benzoate is used. More preferably sodium benzoate is used in an amount of from about 0.05 to 0.5 mass % (based on polyethylene terephthalate).

Suitable glass fibres for use in the polymer composition may have a fibre diameter of from 5 to 20 μm, preferably 8-15 μm, and most preferably 9-11 μm for optimal balance of mechanical properties and processability. The glass fibres preferably have a sizing on their surface that is compatible with polyethylene terephthalate and contains an epoxy- or amino-functional compound. Preferably the sizing contains an epoxy-functional compound. The advantage thereof is a good dispersability in polyethylene terephthalate and improved long-term mechanical properties of the polymer composition, especially fatigue behaviour.

The polymer composition may contain between 10 and 60 wt. % of glass fibres. Preferably the polymer composition contains between 30 and 50 wt. % of glass fibres, most preferably between 35 and 45 wt.%.

The composition preferably contains a thermally conductive filler, to ensure a good thermal conduction of the carrier, to trans[port the heat generated by the LED's. The thermally conductive material preferably has a thermal conductivity λ (W/m·K) that is preferably at least 5 times, more preferably at least 25 times and even more preferably at least 100 times higher than the thermal conductivity of the polymer composition but without the thermally conductive material.

Thermally conductive fillers include for example, fillers of aluminum, aluminum oxide, copper, magnesium, magnesium oxide, brass, silicon nitride, aluminum nitride, boron nitride, zinc oxide, graphite, preferably expanded graphite, PITCH-based carbon fibers and the like. Mixtures of such thermally conductive materials are also suitable. The thermally conductive filler may be in the form of granular powder, particles, whiskers, short fibers, flake, platelet, rice, strand, or spherical-like shapes or any other suitable form. The thermally conductive filler is preferably present in an amount between 1 and 10 wt. % with respect to the total polymer composition, more preferably between 2 and 7 wt. % with respect to the total polymer composition.

Most preferably, the thermally conductive material is expanded graphite, as this is highly effective.

As LDS additive the composition suitably contains an inorganic metal compound of a metal in the d- of f-group of the periodic system. Preferably the inorganic metal compound is a metal oxide. Preferably a copper oxide. Most preferably as LDS additive a mixture of a copper and a nickel compound is used. The conductor tracks may be produced by irradiation of the carrier comprising the LDS additive with a diode pumped Nd:Yag laser to liberate the metal nuclei for the further metallization treatment. In a further step the carrier may brought in a chemical metallization bath, to apply the conductor tracts.

The composition of the carrier may also contain 0-20 mass % of further fibrous or particulate mineral fillers. Preferably filler particles are used, for example talcum or kaolin, because they contribute to the stiffness of the composition without undesirably enhancing anisotropy in properties of the composition.

The polymer composition that is used in the process according to the invention may also contain the usual additives, like stabilisers, anti-oxidants, colorants, processing aids like a mould-release agent, viscosity-modifiers like a chain extension agent, impact-modifiers, etcetera.

Preferably the polymer composition contains less than 5 wt. % of the usual additives, more preferably less than 3 wt. %, most preferably less than 1 wt. %.

1. Light emitting diode (LED) based daylight running light (DRL) comprising a carrier, comprising a polymer composition comprising polyethylene terephthalate, glass fibers and Laser Directed Structure (LDS) additives, the conductor tracks being provided by an LDS process and subsequent metal plating.

2. LED based DRL according to claim 1, wherein the polymer composition contains between 10 and 60 wt. % of glass fibres.

3. LED based DRL according to claim 1, wherein the polymer composition contains between 30 and 50 wt. % of glass fibres.

4. LED based DLR, wherein the polymer composition contains between 35 and 45 wt. % of glass fibers.
